(19) United States
(12) Patent Application Publication
(10) Pub. No.: US 2013/0082183 A1
(43) Pub. Date: Apr. 4, 2013

(54) DIRECTED INFRA-RED COUNTERMEASURE SYSTEM

(71) Applicant: Damien Troy Mudge, Mawson Lakes (AU)

(72) Inventor: Damien Troy Mudge, Mawson Lakes (AU)

(73) Assignee: BAE SYSTEMS AUSTRALIA LIMITED, Edinburgh ,South Australia (AU)

(21) Appl. No.: 13/642,317

(22) PCT Filed: Apr. 19, 2011
(86) PCT No.: PCT/AU2011/000441

§ 371 Date: Dec. 20, 2012

(30) Foreign Application Priority Data
Apr. 20, 2010 (AU) 2010901651

(51) Int. Cl. B01J 19/12; H01L 27/146

(52) U.S. Cl. CPC B01J 19/12; H01L 27/146
USPC 250/349; 250/372; 250/208.1

(57) ABSTRACT

A tracking sensor for a directed infra-red countermeasure (DIRCM) system, the sensor including a first set of image elements in a inner region of the sensor and each having or operable to monitor respective first fields of view; and a second set of image elements in an outer region of the sensor and each having or operable to monitor respective second fields of view. The first fields of view are smaller than the second fields of view or the image elements of the first set provide higher resolution than the image elements of the second set.

### RELATED APPLICATION

This application is based on and claims the benefit of the filing and priority dates of Australian application no. 2010901651 filed 20 Apr. 2010, the content of which as filed is incorporated herein by reference in its entirety.

### FIELD OF THE INVENTION

The present invention relates to a directed infra-red countermeasure system, of particular but by no means exclusive application in the defence of aircraft.

### BACKGROUND OF THE INVENTION

Military aircraft currently operate in war zones where the warfare tactics are predominately asymmetric in nature. The nature of such operations exposes the aircraft to attack by heat seeking, infrared (IR)-guided man-portable-air-defence-systems (MANPADS). MANPADS are attractive weapons in asymmetric warfare because of their light weight (typically less than 20 kg), ease of use, low cost, passive (and hence undetectable) guidance, and range of effectiveness (which can be more than 5 km and up to 12,000 feet altitude).

Existing MANPAD countermeasures include flares, modulated lamp jammers, tactics, and signature management, all of which have cost/performance trade-offs. The primary existing infra-red countermeasure hardware comprises a combination of a Missile Warning System (MWS) and Countermeasure Dispensing System (CMDS), in the form of a controller and flare dispenser. However, only a limited number of flares can be carried on any one mission, so only a limited and defined number of events can be countered, flares—by their nature—cannot be operated covertly, and there are limitations on the locations in which flares can be activated (which may relate to specific sectors or zones around an aircraft and to locality generally).

Directed infra-red countermeasure systems (or DIRCMs) have been developed to overcome some of these perceived limitations, with typical DIRCM systems employing a missile launch detection system in conjunction with a directional infra-red countermeasure laser to interfere with the infra-red guided missile's guidance systems (see, for example, US 2007/0206177 and U.S. Pat. No. 7,378,626). A DIRCM system has no significant limitation on the number of events that may be countered (depending upon the timing of the events), and can also be considered to be covert owing to the wavelengths used by the countermeasure laser, and arguably has fewer limitations as to where it can activated to engage a threat without causing collateral damage to ground forces or accompanying aircraft.

However, DIRCM systems have relatively high unit costs, moderate size and weight, and problems arising from restrictions in access to some technologies (such as lasers and system reprogramming). Also, DIRCM systems are limited in the field of view that can be monitored with any significant resolution, owing to increasingly (and eventually prohibitively) high data processing demands as the field of view is increased.

A typical DIRCM engagement is described by reference to FIG. 1, by reference to a DIRCM system 10 mounted on an aircraft 12. The engagement commences when an infra-red (IR) guided missile 14 is launched at aircraft 12 (from launcher 16). Typically ultraviolet radiation characteristic of a ‘launch spike’ in the light emitted by missile 14 is detected by a Missile Warning System (MWS) of DIRCM system 10. This is known as the ‘eject’ phase. (Missile 14 may also be detected post launch, in which case the missile launch ‘declaration’ from the MWS will be received by the DIRCM system typically in either the subsequent ‘boost’ phase or—quite often—in the later ‘sustain’ phase.)

The MWS provides coordinates of the launch to DIRCM system 10, and in response DIRCM system 10 slews so as to be directed towards those coordinates. By now, missile 14 will be in its boost phase, and in some engagements may already be in the subsequent sustain phase, and will have an infra-red signature typical of the respective phase. The infra-red signature is generally more intense in the boost phase than in the sustain phase, as the rocket motor of the missile 14 is firing; in the sustain phase the infra-red signature will be less intense. Typically DIRCM system 10 is fitted with an infra-red imaging system that allows the infra-red signature of missile 14 to be detected. The DIRCM turret of DIRCM system 10, upon slewing to the designated coordinates, acquires the infra-red signal of the approaching missile 14. The process of finding missile 14 from the scene is termed ‘acquisition’ and, once acquired, DIRCM system 10 tracks the approaching missile 14.

While tracking missile 14, DIRCM system 10 irradiates the approaching missile 14 with an infra-red laser beam 18 that is modulated with known and specific modulation. The purpose of the modulation is to add spurious signals to the infra-red sensor of the approaching missile 14 and induce errors to the guidance system of missile 14 to cause missile 14 to steer away from aircraft 12 (as shown at 14′). Infra-red laser beam 18 is provided by a laser that emits at the correct wavelength(s) to pass through the nose cone of missile 14 and deliver the required modulation (or ‘jam-code’). This process of jamming the missile guidance, if successful, causes optical break lock (i.e. the optical lock of missile 14 on aircraft 12 is broken).

FIG. 2 is a schematic diagram of DIRCM system 10 of the background art. DIRCM system 10 includes a DIRCM system controller 20, which may be essentially a personal computer or a purpose-built processor, and which receives aircraft inertial navigation data and missile position information and automatically controls the response of DIRCM system 10 during a missile engagement. DIRCM system 10 includes inertial feedback sensor 22 for providing DIRCM system controller 20 with inertial feedback sensor data, and a Missile Warning Sensor (MWS) 24 (which may be UV, IR or two-colour, that is, UV/IR) that detects incident missiles and reports their position to DIRCM system controller 20.

DIRCM system 10 also includes a director turret 26, a focal plane array (FPA) sensor/Image Tracker 28 (which may comprise any suitable sensor, such as a CCD or CMOS) and an infra-red countermeasure (IRCM) laser 30. During an engagement, DIRCM system controller 20 receives more precise position data pertaining to missile 14 from FPA sensor 28 and provides turret steering information for tracking missile 14, hence controlling turret 26 to centre missile 14 in its field of view (FOV). DIRCM system 10 also controls IRCM laser 30, both to point towards the identified and tracked position of missile 14 and to emit jamming radiation.

FIG. 3 is a schematic view of turret 26, which includes FPA sensor 28 and a telescope optical lens train 32 for focusing UV/IR light received by turret 26 into an image on FPA sensor 28. Turret 26 includes a motorized, steerable gimbal assembly comprising an azimuth stage 34 and an approximately spherical elevation stage 36 (which is 15 to 20 cm in diameter and includes a window 38 for admitting an IR/UV signal 40) to allow tracking of a threat; azimuth and elevation stages 34, 36 contain mirrors 42, 44 to direct incoming UV/IR light 40 uniformly towards optical train 32 and thence to FPA sensor 28, which transmits the resulting image data to DIRCM system controller 20 for processing.

FPA sensor 28 and a telescope optical train 32 facilitate the fine tracking of a missile. The normal to FPA sensor 28 is oriented along the optical axis of optical train 32 and the plane of FPA sensor 28 is at or near the focal plane of optical train 32, so FPA sensor 28 can provide a measure of angle of arrival of a received signal 42. That is, the infra-red signal 40 from a heat seeking missile is focussed by optical train 32 to a spot on FPA sensor 28, with the location of the spot on FPA sensor 28 indicative of the angle of arrival of the received signal 40. Typically, a signal received on the optical bore-sight of the DIRCM (i.e. when the DIRCM is pointing directly at and centred on the approaching missile) will be located at or near the centre of FPA sensor 28. The position of the image on FPA sensor 28 is processed by DIRCM system controller 20, which outputs position information and controls director turret 26 to track the approaching threat. Typically DIRCM system controller 20 attempts to bring the target onto the optical bore-sight of director turret 26. FIG. 4 is a schematic view 50 of FPA sensor 28 and optical train 32, with incoming IR signal 40 focused by optical train 32 onto FPA sensor 28. FPA sensor 28 is protected by a window 52, through which optical signal 40 passes, and a cold shield. FPA sensor 28 is mounted to a suitable detector cooling element 54.

The field of view (FOV) required by DIRCM system 10 is principally determined by factors associated with the MWS 24, which also gives rise to some of the limitations of a DIRCM system. When a threat is declared by MWS 24, the position declared by MWS 24 is ideally within the FOV of the DIRCM tracking system, which is essentially the effective FOV of FPA sensor 28 resulting from the geometry of turret 26 (and optical train 32). If this is not so, turret 26 must be steered to point towards the position of the threat as identified by the MWS 24, but this is less than ideal as some delay results during which the threat may move significantly. Also, alignment errors between MWS 24 and FPA sensor 28 (and the accuracy of both but particularly of MWS 24) can inhibit the ability of DIRCM system 10 to detect the threat with FPA sensor 28 after its detection by MWS 24 if the threat is not in the FOV of FPA sensor 28 when detected by MWS 24.

### SUMMARY OF THE INVENTION

According to a first aspect of the invention, there is provided a tracking sensor for a DIRCM system, the sensor comprising:
a first set of image elements in a inner region of the sensor and each having or operable to monitor respective first fields of view; and
a second set of image elements in an outer region of the sensor and each having or operable to monitor respective second fields of view;
wherein the first fields of view are smaller than the second fields of view or the image elements of the first set provide higher resolution than the image elements of the second set.

It should be noted that the respective first fields of view (or resolutions) may not be identical, and that the second fields of view (or resolutions) may not be identical. In addition, the sensor may additionally include image elements in the inner region with fields of view greater than those of individual image elements in the outer region, or image elements in the outer region with fields of view smaller than those of individual image elements in the inner region.

In an embodiment, the inner region is a central region, and the outer region comprises all image elements of the sensor not in the inner region.

According to this aspect of the invention, there is provided a DIRCM system, comprising a tracking sensor described above.

In one embodiment, the DIRCM system includes an optical system for directing incoming light (which may be UV, IR or otherwise) onto the first and second sets of image elements of the sensor such that the optical system defines the first and second fields of view and said image elements of said first set have higher resolution than said image elements of said second set.

In another embodiment, the DIRCM system is arranged to combine outputs of groups of image elements of said second set of image elements (such as by summing or averaging the outputs) and thereby increase the respective fields of view of the image elements of said second set.

In another embodiment, the second set of image elements comprise a selected subset of image elements provided in the outer region of said sensor.

In still another embodiment, the DIRCM system includes an optical system for directing incoming light (which may be UV, IR or otherwise) onto the first and second sets of image elements of the sensor such that the optical system defines the first and second fields of view and either (i) is arranged to combine outputs of groups of image elements of said second set of image elements and thereby increase the respective fields of view of the image elements of said second set, or (ii) the second set of image elements comprise a selected subset of image elements provided in the outer region of said sensor.

According to a second aspect of the invention, there is provided a method of image collection (such as in a DIRCM system), comprising:
capturing image data at a first resolution in a first region of a sensor; and
capturing image data at a second resolution in a second region that at least partially surrounds said first region;
wherein said first resolution is greater than said second resolution.

In one embodiment, the first region is a central region of said sensor and the second region comprises all image elements of said sensor not in said first region.

According to this aspect, there is provided a method of image collection (such as in a DIRCM system), comprising:
capturing image data in a first region of a sensor;
capturing image data in a second region of the sensor that at least partially surrounds the first region; and
providing image elements of said sensor in said first region with smaller fields of view than image elements of said sensor in said second region.

The method may comprise providing said image elements of said sensor in said first region with smaller fields of view than image elements of said sensor in said second region with an optical system.

According to a third aspect of the invention, there is provided a method of tracking for directing an infra-red countermeasure, comprising:
capturing image data at a first resolution in a first region of a sensor; and
capturing image data at a second resolution in a second region of said sensor that at least partially surrounds said first region;
wherein said first resolution is greater than said second resolution.

It should be noted that the various features of each of the above aspects of the invention, and the embodiments described below, can be combined as feasible and desired.

### BRIEF DESCRIPTION OF THE DRAWING

In order that the invention may be more clearly ascertained, embodiments will now be described, by way of example, with reference to the accompanying drawing, in which:

FIG. 1 is a schematic view of a typical DIRCM engagement of the background art;

FIG. 2 is a schematic diagram of a DIRCM system of the background art;

FIG. 3 is a schematic view of the DIRCM turret of the DIRCM system of FIG. 2;

FIG. 4 is a schematic view of the focal plane array (FPA) sensor and optical train of the DIRCM system of FIG. 2;

FIG. 5 is a schematic view of the FPA sensor and optical train of the DIRCM system of an embodiment of the invention;

FIG. 6A is a schematic view of the face of the FPA sensor of the DIRCM system of this embodiment;

FIG. 6B is a schematic plot of the Instantaneous Field of View (IFOV) across the face of the FPA sensor of the DIRCM system of this embodiment;

FIG. 7 is a schematic view of the face of the FPA sensor of a DIRCM system of another embodiment;

FIG. 8 is a schematic view of the face of the FPA sensor of a DIRCM system of another embodiment;

FIG. 9 is a schematic view of an optical assembly for use in a DIRCM system constructed according to another embodiment of the present invention, comprising an FPA sensor and optical train;

FIG. 10 is a plot of results from both measurements made with the optical assembly of FIG. 9 and modelling of that optical assembly;

FIG. 11 is an alternative plot of the results from modelling the optical assembly of FIG. 9.

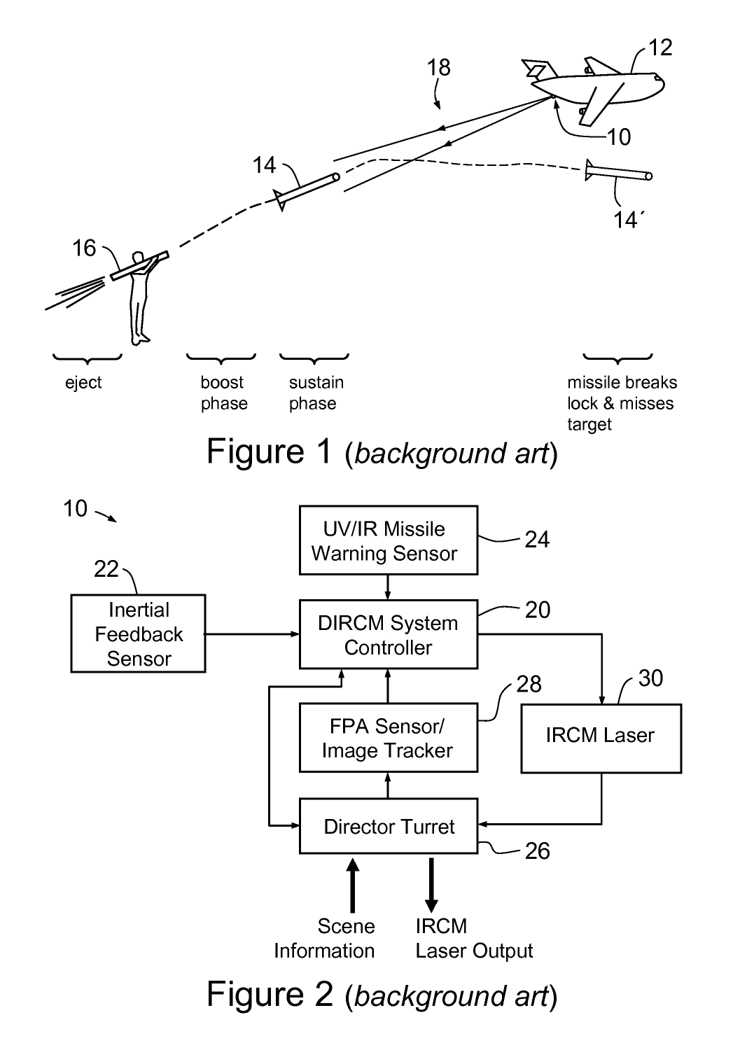

### DETAILED DESCRIPTION

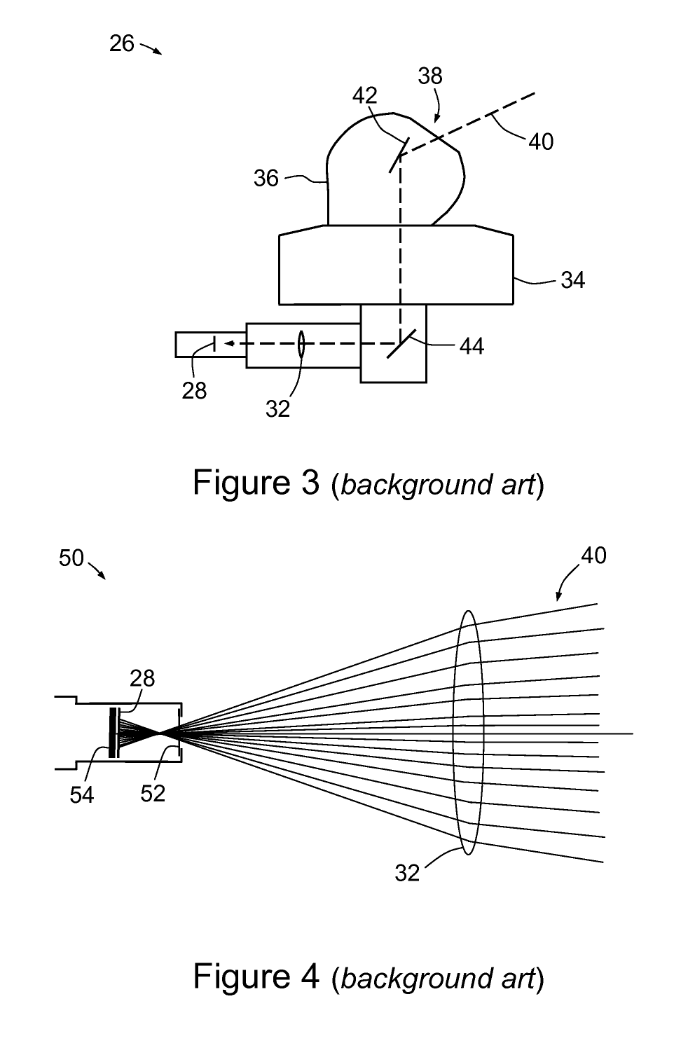

According to an embodiment of the invention, there is provided a DIRCM system that, in broad detail, is comparable to that shown in FIGS. 2 and 3. However, the DIRCM system of this embodiment includes an FPA sensor with a non-uniform field of view.

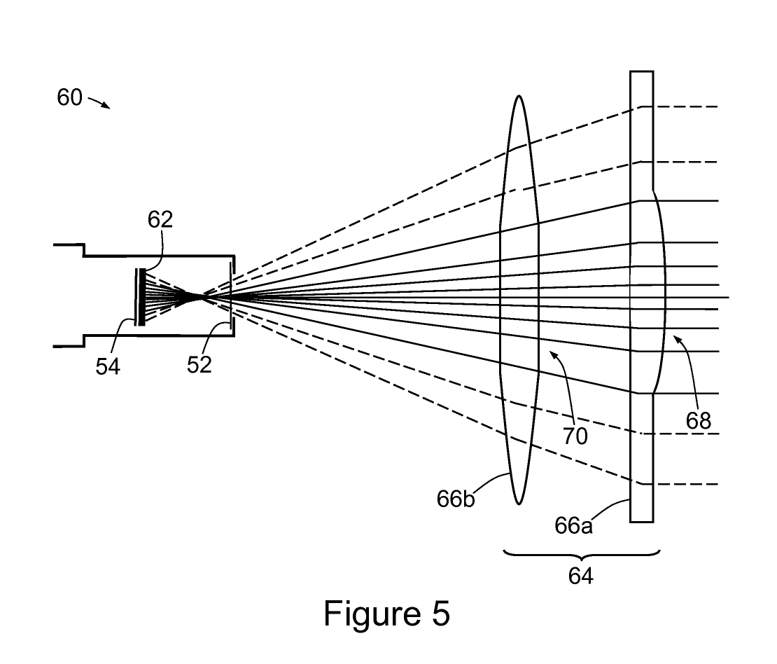

FIG. 5 is a schematic view 60 of the FPA sensor 62 and optical train 64 of the DIRCM system of this embodiment. FPA sensor 62 is essentially conventional, but optical train 64 (shown schematically as comprising first and second lenses 66a, 66b) provides FPA sensor 62 with a non-uniform FOV. First lens 66a has generally parallel faces but with a convex central region 68 that is essentially spherical. Second lens 66b has generally spherical surfaces, but with a substantially planar central region 70.

The dashed lines in this figure represent those signal rays received by turret 26 (travelling from the right to left in this view) that impinge first lens 66a outside its central region 68. Such rays are thus transmitted through the planar outer region of first lens 66a and are then refracted by the outer, spherical region of second lens 66b and focussed onto the outer edges of FPA sensor 62. The solid lines in this figure represent rays received by turret 26 that impinge the central, convex region 68 of first lens 66a and then pass through the planar central region 70 of second lens 66b and focussed onto the inner region of FPA sensor 62.

Consequently, rays focussed onto FPA sensor 62 by second lens 66b (i.e. the dashed rays) represent a greater FOV compared to rays focussed onto FPA sensor 62 by first lens 66a (i.e. the solid rays). As can be seen in this figure, the dashed rays intersect closer to FPA sensor 62 than do the solid rays. Also, there are more solid rays collected from a smaller range of angles than for the dashed rays, as can be observed on the right side of the figure. Such an optical system results in a non-uniform FOV across FPA sensor 62. Each of the image elements near the centre of FPA sensor 62 accept a smaller angular input range (and thus have a smaller instantaneous FOV (IFOV) than those near the edge of FPA sensor 62.

It will be appreciated by those skilled in the art, however, that this particular optical train 64 is exemplary only, and that many alternative optical arrangements could similarly be employed to achieve the same or a similar result (i.e. with a smaller IFOV at the centre of FPA sensor 62 than towards its edge). Any suitable train of optical elements (including reflective or refractive optical elements that utilize spherical, segmented, diffractive or aspheric optical surfaces) could be employed to provide the desired effect of a distorted or non-uniform field of view; in the central region (near the bore-sight) the IFOV is low (and the optical quality of the transmitted signal is high) relative to the outer region. It is expected that the optical efficiency and image quality near the edges of the FOV will be degraded, along with the tracking efficiency, but the outer region of the FOV is intended only for use during MWS hand-off. As the image is moved onto bore-sight by DIRCM system controller 20, image quality and also the tracking efficiency (as the IFOV reduces) will improve.

It will also be appreciated that the particular profile of the IFOV as it changes across the face of FPA sensor 62 can be adjusted as required or desirable by modification of optical train 64. The arrangement of FIG. 5 represents only one potential implementation using refractive optics segmented with plane parallel zones for transmission and spherical surfaces for focussing specific signals. Other possible implementations are envisaged, such as stepped, diffractive or aspheric surfaces to improve optical performance. Alternatively, similar performance could be achieved using reflective optics, or a combination of reflective and refractive optics.

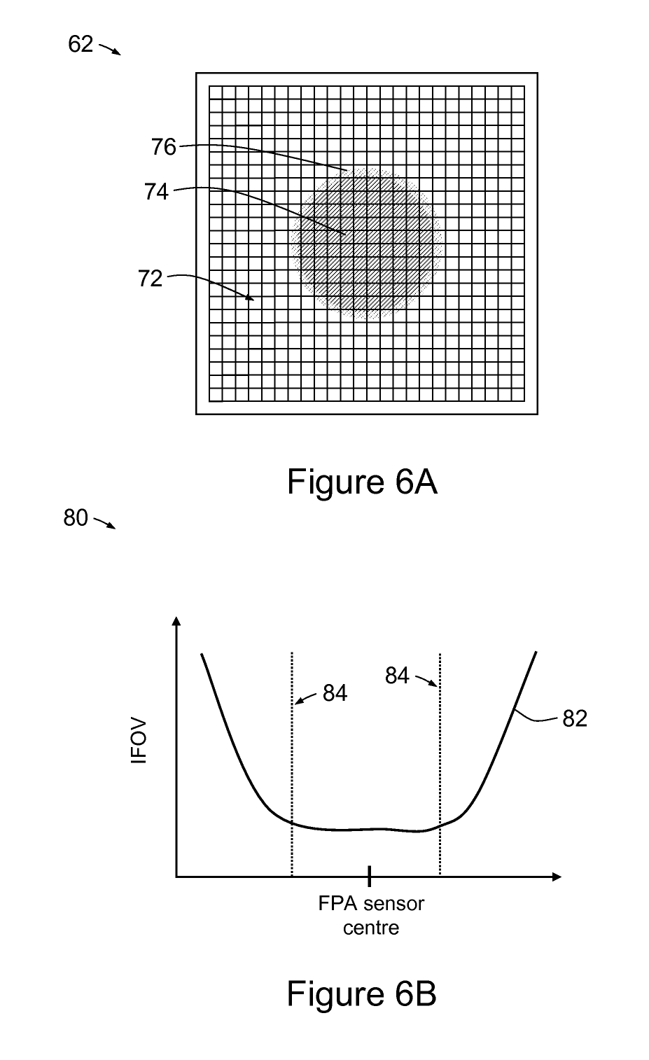

FIG. 6A is a schematic view of the face 70 of FPA sensor 62 according to this embodiment, with individual image elements 72 shown as small squares (again, schematically, as FPA sensor 62 in this embodiment has 256×256 image elements). The shaded, central region 74 represents the region where the tracking resolution is greatest, that is, a ‘fine tracking zone’. It is generally uniform in density (i.e. has a generally uniform IFOV), though reduces in density (i.e. has a somewhat increasing IFOV) towards its periphery 76.

FIG. 6B is a schematic plot 80 of the resulting Instantaneous Field of View (IFOV) 82 across the face of FPA sensor 62. As explained above, IFOV (the angular region detected by each image element) varies across FPA sensor 62; it is greatest (giving relatively poor tracking accuracy) near the edges and smaller (giving relatively greater track accuracy) near the centre. Shaded central region 74 of FIG. 6A corresponds to the region between dashed lines 84 in FIG. 6B, and hence the region where IFOV is substantially constant.

Although the off-axis signal resolution of FPA sensor 62 provided with a non-uniform FOV may be poorer than on-axis, owing to the larger IFOV sampled by the image elements near the edge of FPA sensor 62, in general greater signal intensity is available in the early boost and sustain phases of a heat-seeking missile's flight. Consequently, more signal is available for detection when greatest reliance is placed on the large (i.e. peripheral) IFOV image elements. As the engagement continues the target is moved onto bore-sight, where the optical performance and tracking accuracy is improved for the duration of the engagement.

This embodiment thus can employ a low-cost (with a low number of image elements, such as 256×256) FPA sensor 62 while providing good tracking efficiency near bore-sight while having the provision for a larger FOV at MWS hand-off, with—for example—a 6 to 8 degrees full angle FOV. This reduces FPA sensor cost and signal processing requirements compared with other techniques for increasing FPA sensor FOV (such as by using a 1024×1024 array of image elements).

According to another embodiment of the invention, a non-uniform FOV is provided in a DIRCM system by averaging of peripheral image elements of the FPA sensor. A DIRCM system of this embodiment is, in broad detail, comparable to that shown in FIGS. 2 to 4. As in the optical train of FIG. 4 (and unlike that of FIG. 5), the optical train in this embodiment directs incoming rays uniformly onto an FPA sensor.

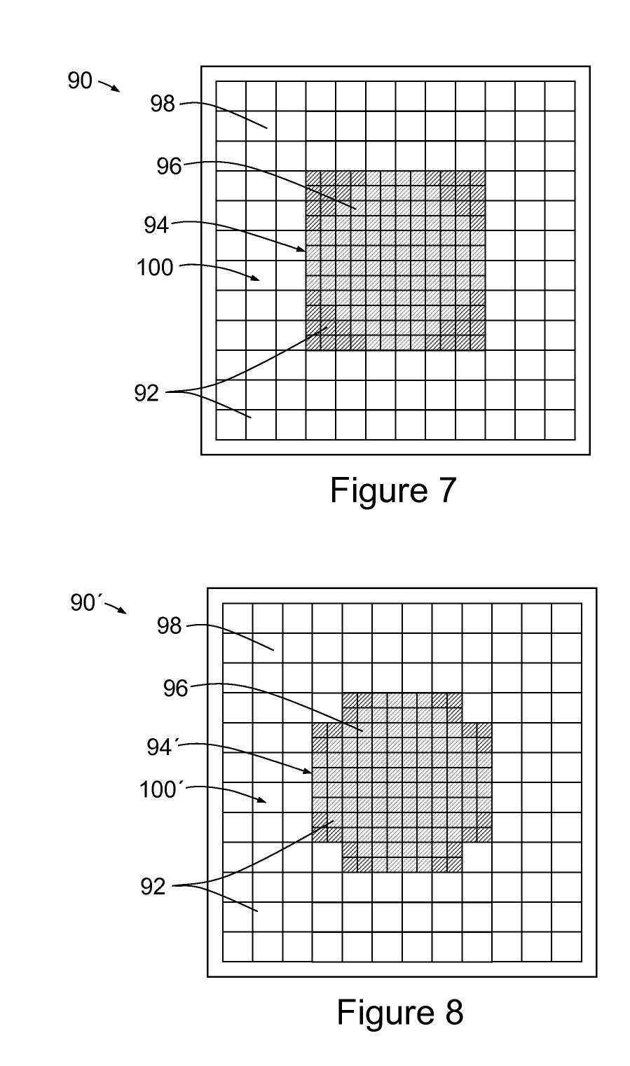

However, the FPA sensor of this embodiment has a larger number of image elements, as shown schematically in FIG. 7 at 90, so is able to provide a greater FOV than can the background art arrangement of FIGS. 2 to 4. Referring to FIG. 7, FPA sensor 90 of this embodiment has more image elements 92 than does FPA sensor 28 of FIG. 3 or FPA sensor 62 of FIG. 6A. The processing demands that would otherwise be created by the use of a larger FPA sensor are addressed as follows.

Even though the optical train of this embodiment provides a uniform FOV at FPA sensor 90, a non-uniform FOV is achieved by sampling, in a central region 94 of FPA sensor 90, all image elements 96, and sampling only the average of groups 98 of image elements (rather than individual image elements) in the outer region 100 of FPA sensor 90. It should be noted that the image elements of outer region 100 are identical in all respects with those of central region 94; in this figure, the groups 98 of image elements are depicted in outer region 100 rather than individual image elements, and hence are larger in the figure. Each of groups 98 of image elements in this embodiment comprises 2×2 image elements, but as will be appreciated this may be varied as desired or required (such that each could comprise, for example, 3×3 image elements, 4×4 image elements, 2×1 image elements, etc).

Indeed, the groups 98 need not all have the same number of image elements. For example, the outputs of successively larger groups of image elements may be summed at correspondingly greater distances from the centre of FPA sensor 90, 92′. For example, immediately around central region 94 there may be a intermediate region of groups each comprising 2×1 image elements, with an outer region of groups each comprising 2×2 image elements thereafter to the edge of FPA sensor 90. This would provide a more staggered change from the low resolution periphery to the higher resolution centre.

Referring to FIG. 7, the outputs of groups 98 of image elements in outer region 100 of FPA sensor 90 are summed electronically and only the result of the summing is read-out to the DIRCM system controller. If any of the image elements in a group 98 receives a target signal, the overall read-out of the group increases with respect to any surrounding groups 98. Additionally pre-processing of the outputs of groups 98 of image elements may be performed if found desirable, such as dividing the summed outputs by four so as to normalize these outputs to the output levels of individual image elements 96 of central region 94.

Thus, although FPA sensor 90 is larger than FPA sensor 62 of the embodiment of FIG. 6A and has a greater FOV, little if any more processing is required of the DIRCM system controller, with less processing being required per image element in outer region 100 than in central region 94.

This embodiment has the particular advantage that the shape of the central and outer regions can be readily modified as desired or found advantageous. FIG. 8, for example, is a schematic view of a variation 90′ of FPA sensor 90. FPA sensor 90′ has a central region 94′ that is more circular than central region 94 of FPA sensor 90 of FIG. 7. This reduces further the data processing load on the DIRCM system controller.

Generally, therefore, this embodiment provides poorer resolution in outer regions 100, 100′ than reading individual image elements, but the processing rate required is thereby reduced—potentially significantly—as compared to reading out the entire FPA sensor 90, 90′. As the DIRCM system controller moves the detected signal onto bore-sight and thus into central region 94, 94′ where more image elements are read-out each cycle, the resolution and thus the tracking accuracy is improved; the effect is therefore similar to the optical technique employed in the embodiment of FIG. 5.

It should be noted that this approach my also be used with an FPA sensor of relatively few image elements (such as the 256×256 image element FPA sensor 62 of FIG. 6A). This would provide no greater FOV than an equivalent system of the background art, but place lower processing demands on the DIRCM system controller.

In one variation, rather than summing the outputs of the image elements in the groups 98, only the outputs of a selected one image element of each group 98 is employed. The selected image element may be, for example, the image element closest to (or furthest from) central region 49, to achieve a symmetrical result.

In one variation, each image elements (as referred to above) may itself comprise plural image elements (such as the photodetectors of a CMOS) at the hardware level.

In another variation, fewer image elements are provided the FPA sensor in the outer region, but this may require the customized manufacture of such an FPA sensor. It is thus expected that the previously described variations of this embodiment will be less expensive and hence more desirable.

In other embodiments, a combination of the optical and electronic approaches described above are used. A non-uniform field of view is achieved using optical elements comparable to those described above as exemplified in FIG. 5, with data read-out from the FPA sensor in the manner described above as exemplified in FIGS. 7 and 8 (i.e. with the summed outputs of group of image elements outputted in the outer regions of the FOV, and the output of all image elements read-out near the centre of the FOV).

The greater FOV means that the process of handing off the threat from MWS 24 to FPA Sensor/Image Tracker 28 should be more reliable. This is expected to be especially so when the embodiments of the present invention output the IRCM laser through turret 26, by projecting the IRCM laser beam into the turret 26 (such as optical train 32 and mirror 44) and, by means of a partially silvered mirror, into the optical path—though in the opposite direction—of the incoming signal, that so that discrepancies between the tracking and irradiating functions of the DIRCM system are minimized.

Thus, in all of the various embodiments described above, effective ‘jamming’ of an approaching missile is provided over an increased FOV than would otherwise be obtained by conventional techniques (that is, for any particular optical FOV, FPA sensor FOV, or processing capacity). Thus, it is expected that a DIRCM system according to these embodiments will be able to track a missile within a small and defined error allowance in order for sufficient infra-red jamming energy to be received by the missile without increasing (or significantly increasing) the processing demands placed on the DIRCM system controller (from a larger FPA sensor of, for example, 512×512 or 1024×1024 image elements), and without loss of resolution in the central region and hence tracking accuracy (as would result from a larger FOV projected onto a conventionally-sized FPA sensor). Also, this is achieved without increasing the divergence of its beam, which would necessitate an increase in the power (and hence expense) of the IRCM laser.

### Example

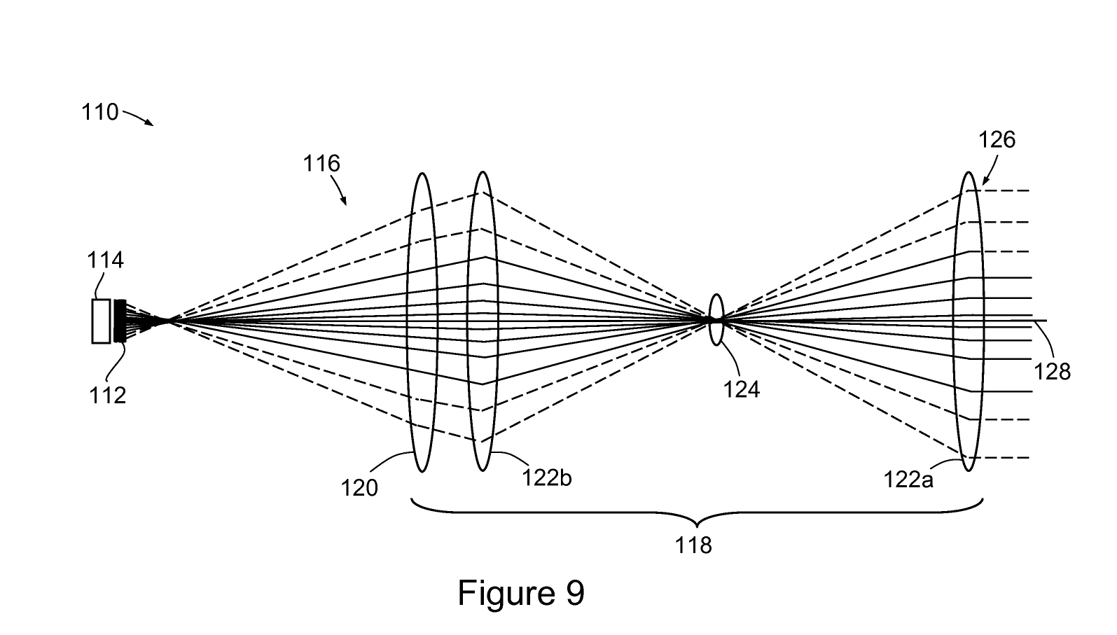

An optical assembly for a DIRCM system, comprising an FPA sensor with a non-uniform field of view, was constructed according to another embodiment of the present invention. This optical assembly is illustrated schematically at 110 in FIG. 9. Optical assembly 110 is comparable to that illustrated in FIG. 5, and includes an FPA sensor 112, upon which optical signal 114 (essentially infra-red radiation) impinges. FPA sensor 112 is an InSb (Indium Antimonide) detector (as InSb is an infra-red sensitive detector material) comprising a 640×512 array with a 15 μm pitch (or pixel spacing). FPA sensor 112 was cooled by using a stirling turbine cooler 116.

Optical assembly 110 also includes an optical train 118 that comprises an objective lens 120 and, on the distal side of objective lens 120 relative to FPA sensor 112 and first (or distal) and second (or proximal) relay lenses 122a, 122b. Objective lens 120 and first and second relay lenses 122a, 122b are identical aspheric lenses of 50 mm diameter, 7 mm thickness and 98 mm focal length, made of AR coated silicon.

Optical assembly 110 also includes a field lens 124 located between relay lenses 122a, 122b and essentially at their respective focal points. Field lens 124 is also of silicon, with a diameter of 12 mm and thickness of 2 mm, but is convex/concave with different radii and an effective focal length of −24 mm. In principle, the distance between relay lenses 122a, 122b is approximately the sum of the focal lengths f1, f2 of relay lenses 122a, 122b, respectively.

However, the actual separation of relay lenses 122a, 122b is not precisely f1+f2, as it is adjusted to take into account the optical length of field lens 124. The combination of relay lenses 122a, 122b has an overall magnification of 1.

The distance from the incident face 126 of first relay lenses 122a to FPA sensor 112 is approximately 300 mm.

The combination of relay lenses 122a, 122b and field lens 124 leads to a non-uniform focal effect such that a non-uniform image, of the type discussed above, is formed on FPA sensor 112.

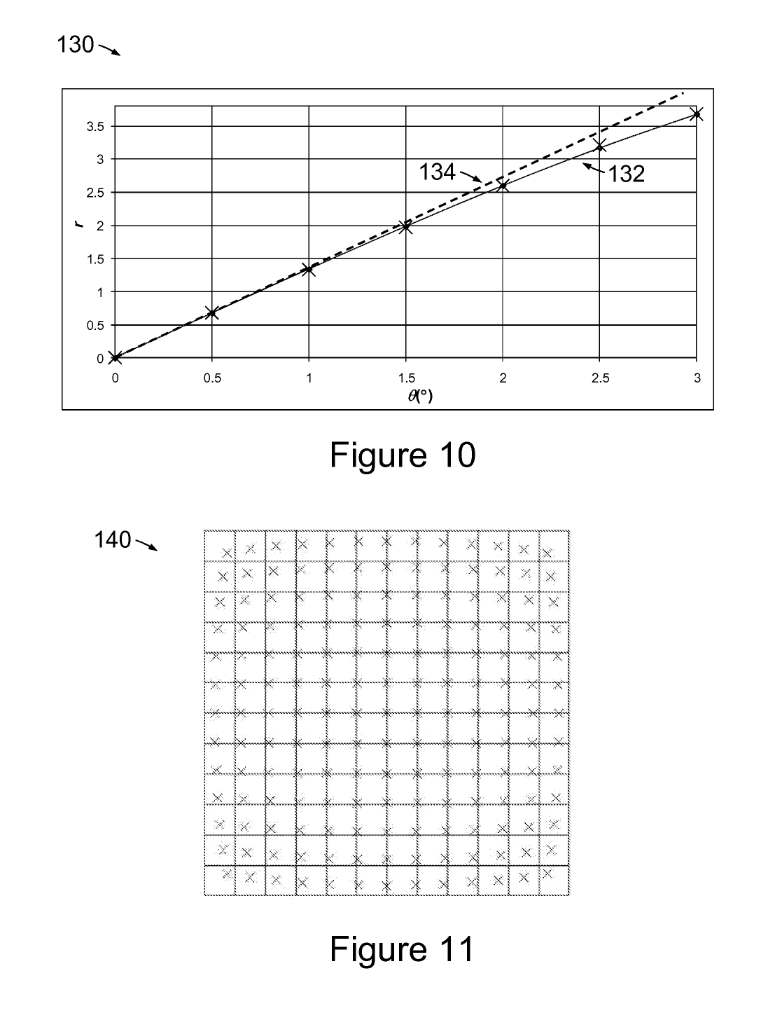

FIG. 10 is a plot 130 of the results of measurements made with the optical assembly 110 of FIG. 9. The radiation source (not shown) comprised a collimated blackbody in the form of a small heater element placed behind a pinhole, with the pinhole at the focus of an off-axis parabola, producing a parallel incident beam. The experimental results are plotted as crosses, and the results from modelling the assembly and its geometry are shown as a solid curve 132. Both are plotted as radial position (r in arbitrary units) from the centre of the FPA sensor 112 in a horizontal plane against angle of incidence (θ in degrees) of the incident radiation, relative to the optical axis 128 of optical assembly 110, on the first optical element encountered by the radiation (viz. relay lens 122b). The data were collected by measuring the spot position at successive values of θ, and involved rotating optical assembly 110 between successive measurements to alter the value of θ.

A dashed, straight line 134 is also plotted, to indicate the approximate relationship between spot position and angle of incidence that would result if a background art arrangement with a uniform field of view (cf. FIG. 4) were employed.

It is evident that there is good agreement between the measured and modelled data and that, as desired, fewer pixels are employed to collect radiation from any fixed portion of the field of view the further one is from optical axis 128 of optical assembly 110.

FIG. 11 is an alternative representation of the model data of FIG. 10 (cf. curve 132 in FIG. 10), showing the distribution of spot positions on the face of FPA sensor 112 for regularly spaced angles of incidence. Owing to the good agreement between the measured and model data, this plot also illustrates the non-uniform field of view of FPA sensor 112.

The performance and degree of non-uniformity of the field of view of FPA sensor 112 can be adjusted as required by appropriate selection of the objective and relay lenses and their properties (including their focal lengths, which need not be identical), and by judicious selection of the field lens and its properties.

For example, the objective and relay lenses 120, 122a, 122b used in this example were aspheric lenses, but other types of lenses (such as simple convex or diffractive) may be employed in variations of this general configuration, provided the combination of lenses produces the desired non-uniform field of view. Similarly, field lens 124—though in this embodiment convex/concave with differing radii—may in other embodiments be aspheric, diffractive or otherwise.

Modifications within the scope of the invention may be readily effected by those skilled in the art. It is to be understood, therefore, that this invention is not limited to the particular embodiments described by way of example hereinabove.

In the claims that follow and in the preceding description of the invention, except where the context requires otherwise owing to express language or necessary implication, the word “comprise” or variations such as “comprises” or “comprising” is used in an inclusive sense, that is, to specify the presence of the stated features but not to preclude the presence or addition of further features in various embodiments of the invention.

Further, any reference herein to prior art is not intended to imply that such prior art forms or formed a part of the common general knowledge in Australia or any other country.

1-17. (canceled)

18. A tracking sensor for a directed infra-red countermeasure (DIRCM) system, said sensor comprising:
a first set of image elements in an inner region of said sensor, each having or operable to monitor respective first fields of view; and
a second set of image elements in an outer region of said sensor, each having or operable to monitor respective second fields of view;
wherein said first fields of view are smaller than said second fields of view or said image elements of said first set provide higher resolution than said image elements of said second set.

19. A sensor as claimed in claim 18, wherein the inner region is a central region, and the outer region comprises:
all image elements of said sensor not in said inner region.

20. A sensor as claimed in claim 18, in combination with a DIRCM system.

21. A sensor and DIRCM system combination as claimed in claim 20, comprising:
an optical system for directing incoming light onto the first and second sets of image elements of said sensor such that the optical system defines the first and second fields of view, and said image elements of said first set have higher resolution than said image elements of said second set.

22. A sensor and DIRCM system combination as claimed in claim 20, wherein said sensor is configured to detect UV, IR or both UV and IR.

23. A sensor and DIRCM system combination as claimed claim 20, arranged to combine outputs of groups of image elements of said second set of image elements for increasing respective fields of view of the image elements of said second set.

24. A sensor and DIRCM system combination as claimed in claim 23, wherein the DIRCM system is arranged to combine the outputs by summing or averaging the outputs.

25. A sensor and DIRCM system combination as claimed in claim 20, wherein the second set of image elements comprise:
a selected subset of image elements provided in the outer region of said sensor.

26. A sensor and DIRCM system combination as claimed in claim 20, comprising:
an optical system for directing incoming light onto the first and second sets of image elements of the sensor such that the optical system defines the first and second fields of view and either (i) is arranged to combine outputs of groups of image elements of said second set of image elements for increasing respective fields of view of the image elements of said second set, or (ii) the second set of image elements comprise a selected subset of image elements provided in the outer region of said sensor.

27. A method of image data collection, comprising:
capturing image data at a first resolution in a first region of a sensor; and
capturing image data at a second resolution in a second region of said sensor that at least partially surrounds said first region;
wherein said first resolution is greater than said second resolution.

28. A method as claimed in claim 27, wherein the first region is a central region of said sensor and the second region comprises all image elements of said sensor not in said first region.

29. A Method as claimed in claim 27, comprising:
directing incoming light with an optical system onto the first and second regions of said sensor such that the first resolution is higher than the second resolution.

30. A method of image data collection, comprising:
capturing image data in a first region of a sensor;
capturing image data in a second region of the sensor that at least partially surrounds the first region; and
providing image elements of said sensor in said first region with smaller fields of view than image elements of said sensor in said second region.

31. A method as claimed in claim 30, comprising:
providing said image elements of said sensor in said first region with smaller fields of view than image elements of said sensor in said second region with an optical system.

32. A method of tracking for directing an infra-red countermeasure, comprising;
capturing image data at a first resolution in a first region of a sensor; and
capturing image data at a second resolution in a second region of said sensor that at least partially surrounds said first region;
wherein said first resolution is greater than said second resolution.
